(19) United States
(12) Patent Application Publication
(10) Pub. No.: US 2026/0227294 A1
(43) Pub. Date: Aug. 6, 2026

(54) Wafer Sampling Recovery and Cleaning System, and Wafer Sampling Recovery and Cleaning Method Using Same

(71) Applicant: WITHTECH INC., Daejeon (KR)

(72) Inventors: Kwon Sik Oh, Osan-si (KR); Keon Soo Lee, Osan-si (KR); Seoung Kyo Yoo, Daejeon (KR)

(21) Appl. No.: 19/152,057

(22) PCT Filed: Dec. 26, 2023
(86) PCT No.: PCT/KR2023/021538

§ 371 Date: Jul. 30, 2025

(30) Foreign Application Priority Data
Jan. 31, 2023 (KR) 10-2023-0012639

(51) Int. Cl. G01N 1/14; B08B 3/02; H10P 70/00

(52) U.S. Cl. CPC G01N 1/14; B08B 3/02; H10P 70/20; G01N 2001/1463

(57) ABSTRACT

A system for sampling wafer, recovering a sampling solution, and cleaning the remaining sampling solution. A wafer sampling recovery and cleaning system and a wafer sampling recovery and cleaning method using same have the effect of increasing the accuracy of a wafer sampling process by including a cleaning unit that cleans the surface of a recovery unit that recovers a sampling solution of a wafer.

### CROSS-REFERENCE TO RELATED APPLICATIONS

This application is the United States national phase of International Patent Application No. PCT/KR2023/021538 filed Dec. 26, 2023, and claims priority to Korean Patent Application No. 10-2023-0012639 filed Jan. 31, 2023, the disclosures of which are hereby incorporated by reference in their entireties.

### BACKGROUND

### Technical Field

The present disclosure relates to a system for sampling a wafer, retrieving a sampling solution, and then cleaning a remaining sampling solution.

### Technical Considerations

A wide variety of hazardous gases are essentially used in the core processes of the semiconductor industry and display industry. These hazardous gases include acidic gases, such as fluorine-based, chlorine-based, brominated, nitric acid-based, and sulfuric acid-based gases, basic gases, such as ammonia and amines, organic compounds, metallic materials, such as Cu, Al, and Si, and dopant materials, such as P and B. In general, the nature of these materials is toxic and have very strong oxidizing power, thereby causing pattern abnormalities or surface peroxidation to make products defective.

In semiconductors, a wafer usually refers to a silicon wafer, which is a thin silicon plate that serves as the basis for making semiconductor integrated circuits. A wafer is made by thinly cutting single crystal silicon with a purity of 99.9999999% and smoothing a surface thereof. The surface of the wafer should not only be free from defects or contamination, but also requires a high degree of flatness because it affects the precision of circuits. Recently, disk-shaped wafers having a thickness of 0.3 mm and a diameter of 15 to 30 cm have been used.

When wafers are assembled and completely inspected, the wafers are cut into individual chips and used as completed integrated circuits. Until used as integrated circuits, the wafers go through a pattern process, an etching process, an ion implantation process, etc., and are then accommodated in a transport enclosure and transported for a next process or accommodated on standby. However, the wafers are chemically contaminated as a large amount of chemicals is supplied during the above process, and the inside of the transport enclosure may be contaminated by the contaminated wafers.

When the wafers are stored inside the contaminated transport enclosure for a long time and the transport enclosure is contaminated above a certain concentration level, the wafers are negatively affected to result in product defects. Therefore, in order to improve the quality of wafer production, a sampling process that quickly and accurately measures not only a gas contamination inside the transport enclosure but also the degree of contamination on the wafer surfaces was very important.

Accordingly, the related art has adopted a method of spraying a sampling solution on the surfaces of the wafers and retrieving and analyzing the sampling solution to check the contaminants on the surface of the wafer. However, this method has a problem in that, in the process of retrieving the sampling solution, some contaminants may remain in a retrieving device that collects and stores the sampling solution and contaminate the retrieving device itself. In this case, the accuracy of wafer sampling is significantly impaired, and thus, a need for a method to overcome this problem has emerged.

Existing technology is described in Korean Patent No. 10-1581376 “Substrate contaminant analysis device and contaminant analysis method using the same”.

### SUMMARY

An object of the present disclosure is to provide a wafer solution retrieving and cleaning system capable of increasing accuracy of a wafer sampling process by including a cleaning unit that cleans a surface of a retrieving unit for retrieving a sampling solution of a wafer, and a wafer solution retrieving and cleaning method using the same.

### technical Solution

In one non-limiting aspect, a wafer sampling solution retrieving and cleaning system applied to a wafer sampling solution device including a seating portion allowing wafer to be seated on one surface thereof and rotating the wafer and a sampling nozzle spraying a sampling solution on a surface of the wafer, includes: a retrieval unit fixed to the seating portion and disposed on an outer portion of the wafer to retrieve the sampling solution on an upper surface of the wafer; and a drain unit receiving the sampling solution from the retrieval unit and discharging the received sampling solution to the outside.

In addition, the retrieval unit may include: a sampling solution storage portion, which is a space at a predetermined depth in which the sampling solution is stored; and a first housing disposed on one side of the sampling solution storage portion and including a blocking wall extending from the sampling solution storage portion in a vertical direction.

In addition, the wafer sampling solution retrieving and cleaning system may further include: a cleaning unit spraying a cleaning solution on the retrieval unit to clean a remaining sampling solution, wherein the cleaning unit includes a cleaning solution storage portion that is a space formed at a predetermined depth in the first housing and a second housing coupled to an upper portion of the first housing, wherein the second housing includes a cover portion formed to cover an entire upper surface of the cleaning solution storage portion.

In addition, the second housing may include a cleaning flow rate adjustment portion extending from the cover portion, surrounding an upper end of the blocking wall, and spaced apart from the upper end of the blocking wall by a predetermined distance.

In addition, the second housing may include a height adjustment portion adjusting a height of the cleaning flow rate adjustment portion, and the height adjustment portion is a bolt that penetrates through the second housing and the first housing.

In addition, the blocking wall may be disposed so that one surface thereof faces the wafer and the sampling solution storage portion, and the one surface of the blocking wall may be formed to be inclined at a predetermined angle from the vertical direction.

In addition, the other side of the sampling solution storage portion may be connected to the drain unit, and the other side surface may be inclined at a predetermined angle from the vertical direction.

In addition, the cleaning unit may include at least one wall cleaning nozzle supplying a cleaning solution to the blocking wall, and the wall cleaning nozzle sprays the cleaning solution directly to the blocking wall.

In addition, the cleaning unit may include at least one wall cleaning nozzle supplying a cleaning solution to the blocking wall, and the wall cleaning nozzle may spray the cleaning solution on an outermost surface of the wafer.

In addition, a spray direction of the wall cleaning nozzle may not be perpendicular to a spray direction of the sampling nozzle but form a predetermined angle.

In another non-limiting aspect, a wafer sampling solution retrieving and cleaning method using a wafer sampling solution retrieving and cleaning system, includes: (a) receiving a wafer sampling solution through a retrieval unit; (b) cleaning a blocking wall of the retrieval unit through a cleaning unit; and (c) discharging the sampling solution to the outside through a drain unit.

In addition, (b) may include at least one of (b1) determining a spray direction of a cleaning solution; and (b2) determining a spray intensity of the cleaning solution, and (b) may include (b3) supplying the cleaning solution to the blocking wall, wherein (b3) follows (b1) or (b2).

In addition, (b1) may include: (b11) including at least one wall cleaning nozzle supplying the cleaning solution to the blocking wall; (b12) adjusting a spray direction of the wall cleaning nozzle toward the blocking wall, when an estimated adhesion strength of particles on the blocking wall is higher than a predetermined reference adhesion strength; and (b13) adjusting the spray direction of the wall cleaning nozzle toward the wafer, when the estimated adhesion strength of particles on the blocking wall is lower than or equal to the predetermined reference adhesion strength, In addition, (b2) may include: (b21) fastening a second housing to an upper portion of a first housing; (b22) injecting the cleaning solution into a cleaning solution storage portion and primarily supplying the cleaning solution to the blocking wall; and (b23) downwardly adjusting a height of the second housing through a height adjustment portion, when the sampling solution of the blocking wall remains by above a reference value.

### Advantageous Effects

The wafer sampling solution retrieving and cleaning system of the present disclosure according to the above configuration and the wafer sampling solution retrieving and cleaning method using the same include the cleaning unit that cleans the surface of the retrieval unit that retrieves the sampling solution of the wafer, thereby improving the accuracy of the wafer sampling process.

### BRIEF DESCRIPTION OF THE DRAWINGS

FIG. 1 is a schematic diagram of a wafer sampling solution retrieving and cleaning system of the present disclosure;

FIG. 2 is a schematic diagram illustrating a first exemplary embodiment of a cleaning unit of the present disclosure;

FIG. 3 is a schematic diagram illustrating a second exemplary embodiment of a cleaning unit of the present disclosure;

FIG. 4 is a schematic diagram illustrating a third exemplary embodiment of a cleaning unit of the present disclosure;

FIG. 5 is a flowchart illustrating a wafer sampling solution retrieving and cleaning method of the present disclosure;

FIG. 6 is a flowchart illustrating detailed operations of a blocking wall cleaning operation of the present disclosure;

FIG. 7 is a flowchart illustrating detailed operations of a cleaning solution direction determination operation of the present disclosure; and FIG. 8 is a flowchart illustrating detailed operations of a cleaning solution strength determination operation of the present disclosure.

### DETAILED DESCRIPTION

Hereinafter, exemplary embodiments of the present disclosure will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present disclosure based on the principle that the inventor is allowed to define terms.

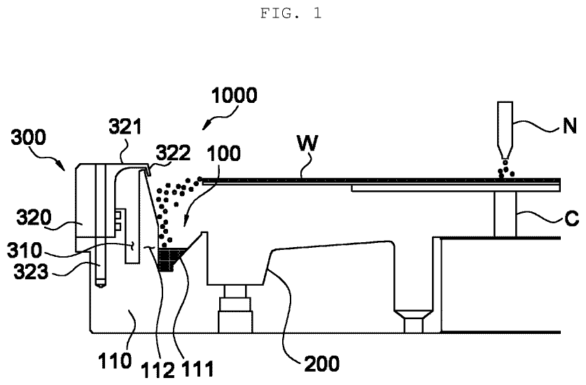

Hereinafter, a basic configuration of a wafer sampling solution retrieving and cleaning system 1000 of the present disclosure will be described with reference to FIG. 1.

The present disclosure relates to a wafer sampling solution retrieving and cleaning system 1000 applied to a wafer W sampling device that includes a seating portion C allowing a wafer W to be seated on one surface thereof and rotating the wafer W and a sampling nozzle N that sprays a sampling solution on a surface of the wafer W. The wafer sampling solution retrieving and cleaning system 1000 of the present disclosure may include a retrieval unit 100 that retrieves a solution that has sampled the surface of the wafer W. The retrieval unit 100 may be fixed to the seating portion C and may be rotated together when the seating portion C rotates. Alternatively, the retrieval unit 100 may be fixed to the seating portion C, but the seating portion C may be configured as a separate component from the part that rotates the wafer W and may maintain a fixed position regardless of rotation of the wafer W. The retrieval unit 100 is disposed along an outer edge of the wafer W and may retrieve the sampling solution on an upper surface of the wafer W scattered by centrifugal force when the wafer W rotates.

The retrieval unit 100 may include a first housing 110 including a sampling solution storage portion 111, which is a space having a predetermined depth in which the sampling solution is stored, and a blocking wall 112 disposed on one side of the sampling solution storage portion 111 and extending in a vertical direction from the sampling solution storage portion 111. The sampling solution storage portion 111 and the blocking wall 112 may be configured as a single component. The maximum height of the blocking wall 112 in the vertical direction may be higher than the height of the wafer W attached to the seating portion C. Accordingly, the sampling solution droplets scattered from the outer portion of the wafer W may hit the blocking wall 112 and be accommodated in the sampling solution storage portion 111.

In addition, the wafer sampling solution retrieving and cleaning system 1000 of the present disclosure may include a drain unit 200. The drain unit 200 may receive the sampling solution from the retrieval unit 100 and discharge the sampling solution to the outside. The discharged sampling solution may be analyzed to determine the presence or absence of contaminants on the surface of the wafer W. It is preferable that the sampling solution be stored in the retrieval unit 100 before being discharged to the outside through the drain unit 200.

In addition, the wafer sampling solution retrieving and cleaning system 1000 of the present disclosure may include a cleaning unit 300. The cleaning unit 300 may spray a cleaning solution on the retrieval unit 100 to clean the sampling solution remaining in the retrieval unit 100. The cleaning solution may be ultrapure water or hot UPW. By including the cleaning unit 300, a surface of the retrieval unit 100 may be maintained to be clean, thereby improving accuracy in analyzing the sampling solution. In more detail, when contaminants contained in the sampling solution settle in the sampling solution storage portion 111 or the sampling solution splashes and adheres to the blocking wall 112, the cleaning unit 300 may clean the surface of the retrieval unit 100, thereby increasing the accuracy in sampling solution analysis.

Furthermore, the blocking wall 112 may be arranged so that one surface thereof faces the wafer W and the sampling solution storage portion 111. Accordingly, when the sampling solution scatters from the surface of the wafer W, the sampling solution may hit the blocking wall 112 and be collected by the sampling solution storage portion 111. In addition, in more detail, one surface of the blocking wall 112 may be formed to be inclined at a predetermined angle from the vertical direction. Accordingly, the sampling solution that has hit the blocking wall 112 may be induced to flow into the sampling solution storage portion 111 along the inclined surface.

In addition, the other side of the sampling solution storage portion 111 may be connected to the drain unit 200, and the other side surface may be formed to be inclined at a predetermined angle from the vertical direction. That is, as shown in FIG. 1, an internal cross-sectional area of the sampling solution storage portion 111 may be designed to increase from the bottom to the top of the sampling solution storage portion 111 in the vertical direction. Accordingly, it is possible to minimize precipitation of contaminants contained in the sampling solution on a lower surface of the sampling solution storage portion 111.

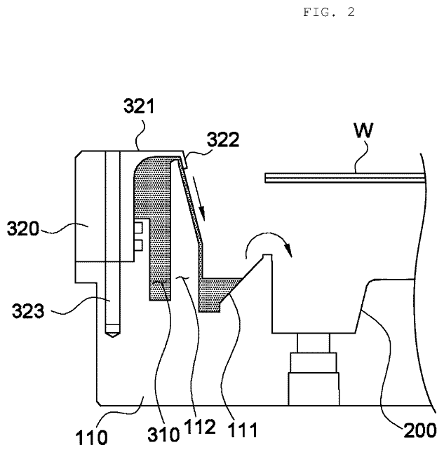

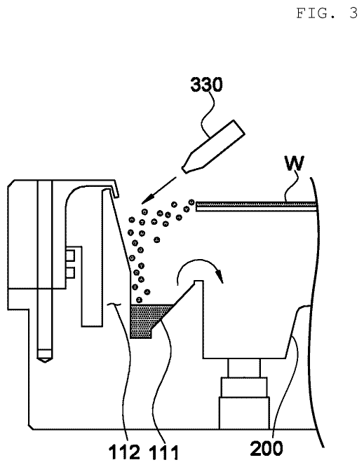

Hereinafter, a first exemplary embodiment of the cleaning unit 300 of the present disclosure will be described in more detail with reference to FIG. 2.

In the first exemplary embodiment of the cleaning unit 300 shown in FIG. 2, the cleaning unit 300 may include a cleaning solution storage portion 310, which is a space formed at a predetermined depth in the first housing 110 and a second housing 320 coupled to an upper portion of the first housing 110. The second housing 320 may include a cover portion 321 formed to cover the entire upper surface of the cleaning solution storage portion 310. Accordingly, the cleaning solution may be accommodated in a space surrounded by the cleaning solution storage portion 310, the cover portion 321, and the blocking wall 112. The cleaning solution storage portion 310 may be connected to a pump that provides the cleaning solution.

In addition, the second housing 320 may include a cleaning flow rate adjustment portion 322 extending from the cover portion 321, surrounding an upper end of the blocking wall 112, and spaced apart from the upper end of the blocking wall 112. Accordingly, when the cleaning solution is injected into the cleaning solution storage portion 310 using a pump, etc., and the cleaning solution fills the space surrounded by the cleaning solution storage portion 310, the cover portion 321, and the blocking wall 112, the cleaning solution, which overflows, may leak through a gap between the cleaning flow rate adjustment portion 322 and the blocking wall 112 to clean the blocking wall 112.

Furthermore, the second housing 320 may include a height adjustment portion 323 that adjusts the height of the cleaning flow rate adjustment portion 322, and the height adjustment portion 323 may be a bolt penetrating through the second housing 320 and the first housing 110. When the height of the second housing 320 is adjusted through the height adjustment portion 323, a distance between the cleaning flow rate adjustment portion 322 and the blocking wall 112 may be adjusted, and a flow velocity of the cleaning solution may be determined accordingly. That is, assuming that the cleaning solution is injected at a constant flow rate by a pump, etc., as the distance between the cleaning flow rate adjustment portion 322 and the blocking wall 112 is longer, the flow velocity may be slower, and as the distance therebetween is shorter, the flow velocity may be faster. (A spray intensity may increase.)

Hereinafter, a second exemplary embodiment of the cleaning unit 300 will be described in more detail with reference to FIG. 3.

As shown in FIG. 3, the cleaning unit 300 may include at least one wall cleaning nozzle 330 that supplies the cleaning solution to the blocking wall 112. In the second exemplary embodiment of the cleaning unit 300, the wall cleaning nozzle 330 may spray the cleaning solution directly onto the blocking wall 112. Accordingly, contaminants adhered to the surface of the blocking wall 112 may be directly cleaned off using the cleaning solution. At this time, a cleaning intensity may be easily adjusted by adjusting the spray intensity of the wall cleaning nozzle 330.

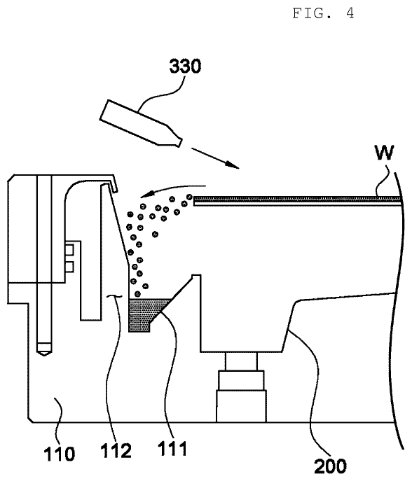

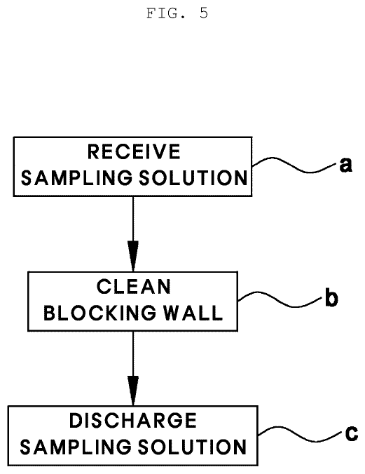

Hereinafter, a third exemplary embodiment of the cleaning unit 300 will be described in more detail with reference to FIG. 4.

As shown in FIG. 4, the cleaning unit 300 may include at least one wall cleaning nozzle 330 that supplies the cleaning solution to the blocking wall 112. In the third exemplary embodiment of the cleaning unit 300, the wall cleaning nozzle 330 may spray the cleaning solution on the outermost surface of the wafer W. Accordingly, the sampling solution on the wafer W and the cleaning solution may be scattered together by centrifugal force to clean the blocking wall 112. Accordingly, damage to the blocking wall 112 may be minimized and contaminants on the blocking wall 112 may be removed.

At this time, a spray direction of the wall cleaning nozzle 330 may form a predetermined angle rather than being perpendicular to the spray direction of the sampling nozzle N. In the case of the sampling nozzle N, the sampling solution is mainly sprayed in a direction perpendicular to the surface of the wafer W, and the wall cleaning nozzle 330 may spray the cleaning solution in a direction having a predetermined inclination angle, rather than being perpendicular to the surface of the wafer W, to maximize scattering efficiency or by considering the arrangement of the nozzle and pump. Accordingly, cleaning efficiency may be maximized.

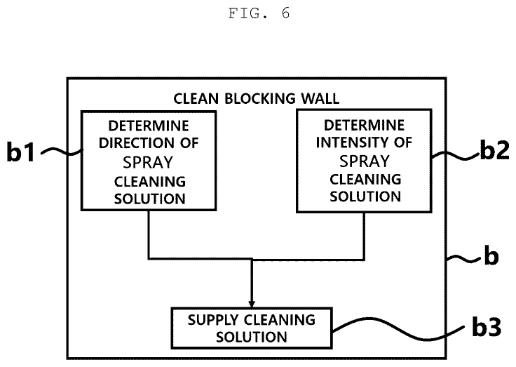

Hereinafter, a wafer sampling solution retrieving and cleaning method of the present disclosure will be described with reference to FIGS. 5 to 8.

As shown in FIG. 5, the wafer sampling solution retrieving and cleaning method using the wafer sampling solution retrieving and cleaning system 1000 may include operation (a) of receiving a wafer W sampling solution through the retrieval unit 100, operation (b) of cleaning the blocking wall 112 of the retrieval unit 100 through the cleaning unit 300, and operation (c) of discharging the sampling solution to the outside through the drain unit 200. At this time, in operation (a), the retrieval unit 100 may be disposed along the outer portion of the wafer W to retrieve the sampling solution on the upper surface of the wafer W scattered by the centrifugal force when the wafer W rotates. In addition, in operation (c), the drain unit 200 may be connected to the sampling solution storage portion 111, so that when a predetermined or more sampling solution is accommodated in the sampling solution storage portion 111, the drain unit 200 may receive the sampling solution and discharge the sampling solution to the outside. The discharged sampling solution may be analyzed to determine the presence or absence of contaminants on the surface of the wafer W. It is preferable that the sampling solution be stored in the retrieval unit 100 until it is discharged to the outside through the drain unit 200.

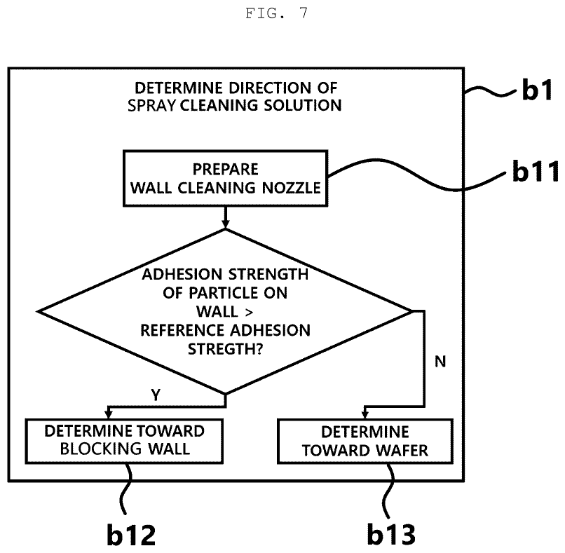

At this time, as shown in FIG. 6, operation (b) may include at least one of operation (b1) of determining a spray direction of the cleaning solution and operation (b2) of determining a spray intensity of the cleaning solution, and may include operation (b3) of supplying the cleaning solution to the blocking wall 112, and here, operation (b3) may follow operation (b1) or operation (b2).

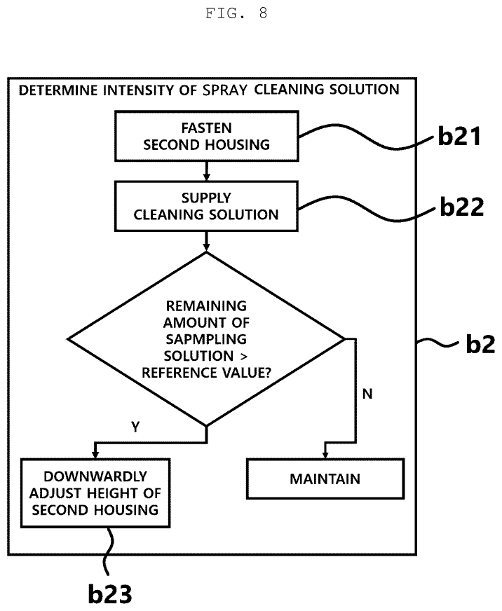

In more detail, as shown in FIG. 7, operation (b1) may include operation (b11) of including at least one wall cleaning nozzle 330 supplying a cleaning solution to the blocking wall 112 and may include operation (b12) of adjusting a spray direction of the wall cleaning nozzle 330 toward the blocking wall 112 when estimated adhesion strength of particles on the blocking wall 112 is higher than a predetermined reference adhesion strength. Accordingly, contaminants adhered to the surface of the blocking wall 112 may be directly cleaned using the cleaning solution. At this time, a cleaning intensity may be easily adjusted by adjusting a spray intensity of the wall cleaning nozzle 330.

In addition, the operation (b1) may include operation (b13) of adjusting the spray direction of the wall cleaning nozzle 330 toward the wafer W when the estimated adhesion strength of the particles on the blocking wall 112 is lower than or equal to the predetermined reference adhesion strength. Accordingly, the sampling solution and the cleaning solution on the wafer W may be scattered together by the centrifugal force to clean the blocking wall 112. Accordingly, damage to the blocking wall 112 may be minimized and the contaminants on the blocking wall 112 may be removed. At this time, the spray direction adjustment method of the wall cleaning nozzle 330 in operations (b12) and (b13) may be manual or may be an automatic adjustment method connected to a controller.

In addition, as shown in FIG. 8, operation (b2) may include operation (b21) of fastening the second housing 320 to the upper portion of the first housing 110 and operation (b22) of injecting the cleaning solution into the cleaning solution storage portion 310 and primarily supplying the cleaning solution to the blocking wall 112. In more detail, when the cleaning solution is injected into the cleaning solution storage portion 310 using a pump, etc. and the cleaning solution fills the space surrounded by the cleaning solution storage portion 310, the cover portion 321, and the blocking wall 112, the cleaning solution, which overflows, may leak through a gap between the cleaning flow rate adjustment portion 322 and the blocking wall 112 to clean the blocking wall 112.

At this time, if the sampling solution of the blocking wall 112 remains above a reference value after operation (b22), the intensity of the cleaning solution may be too low, and therefore, operation (b2) may include operation (b23) of downwardly adjusting the height of the second housing 320 through the height adjustment portion 323. The height adjustment portion 323 may be a bolt that penetrates through the second housing 320 and the first housing 110. Accordingly, the distance between the cleaning flow rate adjustment portion 322 and the blocking wall 112 may be shortened, so that a flow velocity may increase (the spray intensity may increase).

The present disclosure should not be construed to being limited to the above-mentioned exemplary embodiment. The present disclosure may be applied to various fields and may be variously modified by those skilled in the art without departing from the scope of the present disclosure claimed in the claims. Therefore, it is obvious to those skilled in the art that these alterations and modifications fall in the scope of the present disclosure.

### DETAILED DESCRIPTION OF MAIN ELEMENTS

1000: Wafer sampling solution retrieving and cleaning system
100: retrieval unit
110: first housing
111: sampling solution storage portion
112: blocking wall
200: drain unit
300: cleaning unit
310: cleaning solution storage portion
320: second housing
321: cover portion
322: cleaning flow rate adjustment portion
323: height adjustment portion
330: wall cleaning nozzle
W: wafer
N: sampling nozzle
C: seating portion

1. A wafer sampling solution retrieving and cleaning system applied to a wafer sampling solution device comprising a seating portion allowing wafer to be seated on one surface thereof and rotating the wafer and a sampling nozzle spraying a sampling solution on a surface of the wafer, the wafer sampling solution retrieving and cleaning system comprising:
a retrieval unit fixed to the seating portion and disposed on an outer portion of the wafer to retrieve the sampling solution on an upper surface of the wafer; and
a drain unit receiving the sampling solution from the retrieval unit and discharging the received sampling solution to the outside.

2. The wafer sampling solution retrieving and cleaning system of claim 1, wherein
the retrieval unit comprises:
a sampling solution storage portion, which is a space at a predetermined depth in which the sampling solution is stored; and
a first housing disposed on one side of the sampling solution storage portion and comprising a blocking wall extending from the sampling solution storage portion in a vertical direction.

3. The wafer sampling solution retrieving and cleaning system of claim 2, further comprising:
a cleaning unit spraying a cleaning solution on the retrieval unit to clean a remaining sampling solution,
wherein the cleaning unit comprises a cleaning solution storage portion that is a space formed at a predetermined depth in the first housing and a second housing coupled to an upper portion of the first housing,
wherein the second housing comprises a cover portion formed to cover an entire upper surface of the cleaning solution storage portion.

4. The wafer sampling solution retrieving and cleaning system of claim 3, wherein
the second housing comprises a cleaning flow rate adjustment portion extending from the cover portion, surrounding an upper end of the blocking wall, and spaced apart from the upper end of the blocking wall by a predetermined distance.

5. The wafer sampling solution retrieving and cleaning system of claim 4, wherein
the second housing comprises a height adjustment portion adjusting a height of the cleaning flow rate adjustment portion, and
the height adjustment portion is a bolt that penetrates through the second housing and the first housing.

6. The wafer sampling solution retrieving and cleaning system of claim 2, wherein
the blocking wall is disposed so that one surface thereof faces the wafer and the sampling solution storage portion, and
the one surface of the blocking wall is formed to be inclined at a predetermined angle from the vertical direction.

7. The wafer sampling solution retrieving and cleaning system of claim 2, wherein
the blocking wall is disposed so that one surface thereof faces the wafer and the sampling solution storage portion, and
the one surface of the blocking wall is formed to be inclined at a predetermined angle from the vertical direction.

8. The wafer sampling solution retrieving and cleaning system of claim 2, wherein
the cleaning unit comprises at least one wall cleaning nozzle supplying a cleaning solution to the blocking wall, and
the wall cleaning nozzle sprays the cleaning solution directly to the blocking wall.

9. The wafer sampling solution retrieving and cleaning system of claim 2, wherein
the cleaning unit comprises at least one wall cleaning nozzle supplying a cleaning solution to the blocking wall, and
the wall cleaning nozzle sprays the cleaning solution on an outermost surface of the wafer.

10. The wafer sampling solution retrieving and cleaning system of claim 9, wherein
a spray direction of the wall cleaning nozzle is not perpendicular to a spray direction of the sampling nozzle but forms a predetermined angle.

11. A wafer sampling solution retrieving and cleaning method using a wafer sampling solution retrieving and cleaning system, the wafer sampling solution retrieving and cleaning method comprising:
(a) receiving a wafer sampling solution through a retrieval unit;
(b) cleaning a blocking wall of the retrieval unit through a cleaning unit; and
(c) discharging the sampling solution to the outside through a drain unit.

12. The wafer sampling solution retrieving and cleaning method of claim 11, wherein
step (b) comprises at least one of:
(b1) determining a spray direction of a cleaning solution; and
(b2) determining a spray intensity of the cleaning solution, and
step (b) comprises (b3) supplying the cleaning solution to the blocking wall, wherein (b3) follows (b1) or (b2).

13. The wafer sampling solution retrieving and cleaning method of claim 12 wherein
step (b1) comprises:
(b11) at least one wall cleaning nozzle supplying the cleaning solution to the blocking wall;
(b12) adjusting a spray direction of the wall cleaning nozzle toward the blocking wall, when an estimated adhesion strength of particles on the blocking wall is higher than a predetermined reference adhesion strength; and
(b13) adjusting the spray direction of the wall cleaning nozzle toward the wafer, when the estimated adhesion strength of particles on the blocking wall is lower than or equal to the predetermined reference adhesion strength.

14. The wafer sampling solution retrieving and cleaning method of claim 12, wherein
step (b2) comprises:
(b21) fastening a second housing to an upper portion of a first housing;
(b22) injecting the cleaning solution into a cleaning solution storage portion and primarily supplying the cleaning solution to the blocking wall; and
(b23) downwardly adjusting a height of the second housing through a height adjustment portion, when the sampling solution of the blocking wall remains above a reference value.
